(19) United States
(12) Patent Application Publication
(10) Pub. No.: US 2012/0262886 A1
(43) Pub. Date: Oct. 18, 2012

(54) Display Device

(76) Inventor: Yasuhiko YAMAGISHI, Mobara (JP)

(21) Appl. No.: 13/442,267

(22) Filed: Apr. 9, 2012

(30) Foreign Application Priority Data
Apr. 18, 2011 (JP) 2011-092378

(51) Int. Cl. H05K 7/00

(52) U.S. Cl. 361/749

(57) ABSTRACT

A wiring area on a substrate is expanded and the width of the substrate is reduced to achieve a smaller display device at lower cost. The display device includes a display panel, a circuit board, and a flexible printed circuit board connecting the display panel and the circuit board, and the circuit board and the flexible printed circuit board are electrically connected to each other via an anisotropic conductive film. Crimp contacts 15 in the mounting area of the flexible printed circuit board 11 and crimp dummy terminals 16 outside the mounting area are provided on the circuit board, and some of the crimp dummy terminals act as test terminals 18 for crimp resistance measurement, and the crimp contacts 15 and the test terminals 18 are electrically connected to each other on the circuit board.

The present application claims priority from Japanese patent application JP2011-092378 filed on Apr. 18, 2011, the content of which is hereby incorporated by reference into this application.

### BACKGROUND OF THE INVENTION

1. Field of the Invention

The present invention relates to display device such as liquid crystal display device and, in particular, to a display device having an improved structure for measuring an electrical connection between a substrate having an electronic device and a flexible printed circuit board.

2. Description of the Related Art

For example, a liquid crystal display device includes a liquid crystal display panel having a pixel area on a substrate, a printed circuit board (PCB) having electronic devices such as an IC, and a flexible printed circuit board (FPC) for electrically connecting the substrate of the liquid crystal display panel and the terminals of the printed circuit board. To reduce the size of the liquid crystal display device, driver ICs may be disposed on the substrate of the liquid crystal display panel (COG: Chip on Glass) or on the flexible printed circuit board (COF: Chip on Film). In recent years, liquid crystal display devices have been multicolored with a higher degree of definition and thus the number of input or output terminals of substrates has been increased accordingly. Thus, an anisotropic conductive film (ACF) is used for electrically connecting a substrate and a flexible printed circuit board (FPC). In this case, a measurement is necessary to confirm whether the anisotropic conductive film is properly connected or not.

As a technique of measuring a connected state by measuring the contact resistance of an anisotropic conductive film, Japanese Patent Laid-Open No. 2005-175492 discloses a method of measuring a contact resistance at a connection of an anisotropic conductive film used for joining driver ICs, a flexible printed circuit board, or other driver integrated circuits onto a liquid crystal display panel. In this method, a test pad array is provided on the surface of the liquid crystal display panel, the test pad array is electrically connected to a set of terminal pads installed on the surface of the liquid crystal display panel, the set of terminal pads is joined to electronic devices via a conductive material, and the contact resistance of the conductive material connecting the test pad array and the electronic devices is measured using the test pad array (see Abstract).

Japanese Patent Application Laid-Open Publication No. 2007-52146 discloses a liquid crystal display device including a pixel area containing multiple display pixels on a substrate, a drive circuit connected to the pixel area, and an external connection area connected to an external circuit outside the pixel area, the liquid crystal display device further including metal bumps disposed on the ends of the back side of the drive circuit, first and second wiring layers that are disposed on the substrate so as to extend below the metal bumps of the drive circuit from the external connection area and are connected to the metal bumps via an anisotropic conductive film, and first and second terminals that are disposed in the external connection area and are connected to the first and second wiring layers, respectively. Before the external circuit is connected, the crimp resistance of the drive circuit to the substrate is measured using the first and second terminals. After the external circuit is connected, the first and second terminals are used as input terminals to the external circuit (see claims 1 and 2).

### SUMMARY OF THE INVENTION

Generally, a liquid crystal display device for tablet use or mobile use includes a TFT drive circuit and a driver connecting portion which are mounted on the same substrate in view of a module structure and the cost. Thus, smaller substrate widths have been strongly demanded for liquid crystal display devices. The number of circuit components has been reduced and multilayer substrates have been used to reduce the widths of substrates but a reduction in width is limited.

As described in Japanese Patent Application Laid-Open Publication No. 2005-175492, the substrate of the liquid crystal display device includes test pads for measuring a contact resistance at a connection of the anisotropic conductive film. The provision of the test pads leads to difficulty in reducing the width of the substrate.

Japanese Patent Application Laid-Open Publication No. 2007-52146 describes the terminals that are disposed in the external connection area as terminals for measuring a contact resistance, which eliminates the need for providing dedicated terminals for measurement. This technique is usable for measurement of a contact resistance of the drive circuit provided on the substrate but is not usable for measurement of a contact resistance of an external circuit such as an FPC.

The present invention increases a wiring area on a substrate and reduces the width of the substrate by improving the configuration of a test terminal for measuring a crimp resistance at a connection of an anisotropic conductive film in a display device, thereby achieving a smaller display device at lower cost.

In order to address the foregoing problem, a display device according to the present invention is configured such that test terminals for crimp resistance measurement on a substrate are disposed at dummy terminal portions outside the mounting area of electronic components and the test terminals and crimp contacts are electrically connected to each other on the substrate.

An aspect of the present invention is a display device including a display panel, a circuit board, and a flexible printed circuit board connecting the display panel and the circuit board, the flexible printed circuit board being electrically connected to at least one of substrates of the display panel and the circuit board via an anisotropic conductive film, wherein the one of the substrates and the circuit board has a mounting area superimposed on the flexible printed circuit board, the mounting area of the one of the substrates and the circuit board contains multiple first terminals, an area other than the mounting area contains second terminals unconnected to the first terminals and third terminals respectively connected to the first terminals, and the first terminals include terminals connected to the third terminals and terminals unconnected to the third terminals.

In the display device according to the aspect of the present invention, the first terminals, the second terminals, and the third terminals may be arranged in a line along one side of the one of the substrates and the circuit board.

In the display device according to the aspect of the present invention, the third terminal may have a different shape from the second terminal.

In the display device according to the aspect of the present invention, the second terminals and the third terminals may be identical in shape and the third terminals may be spaced at intervals different from those of the second terminals.

In the display device according to the aspect of the present invention, the second terminals may be disposed on both sides of the first terminals and the third terminals may be disposed on the opposite side of the second terminals from the first terminals.

In the display device according to the aspect of the present invention, the display panel may include a drive circuit installed by COG mounting.

In the display device according to the aspect of the present invention, the flexible printed circuit board may include a drive circuit installed by COF mounting.

In the display device according to the aspect of the present invention, the display panel may be one of a liquid crystal display panel, an organic EL display panel, and a plasma display panel:

According to the aspect of the present invention, test terminals for crimp resistance measurement are disposed at crimp dummy terminal portions. Thus, the wiring area of the test terminals can be used as a mounting area of electronic components, the wiring area can be expanded on the substrate and the width of the substrate can be reduced, thereby achieving a smaller display device at lower cost. Furthermore, the test terminals for crimp resistance measurement are disposed on both ends of a crimp area and are arranged in a line on the printed circuit board, thereby facilitating measurement. Moreover, a crimp resistance can be automatically measured by a prober.

### BRIEF DESCRIPTION OF THE DRAWINGS

Embodiments of the present invention will be described in detail based on the following figures, wherein:

FIG. 1 illustrates the shapes and structures of crimp contacts according to a first embodiment of the present invention;

FIG. 2 is a block diagram illustrating a schematic configuration of a liquid crystal display device;

FIG. 3 illustrates a structural example of the liquid crystal display device;

FIG. 4 illustrates a terminal layout area for connecting an FPC or COFs by crimping on a drain substrate;

FIG. 5 illustrates the shapes and structures of conventional crimp contacts;

FIG. 6 illustrates the shapes and structures of crimp contacts according to a second embodiment of the present invention; and

FIG. 7 illustrates the shapes and structures of crimp contacts according to a third embodiment of the present invention.

### DETAILED DESCRIPTION OF THE INVENTION

Before an explanation about embodiments of the present invention, the following will describe a display device to which the present invention is applied. The display device is a liquid crystal display device.

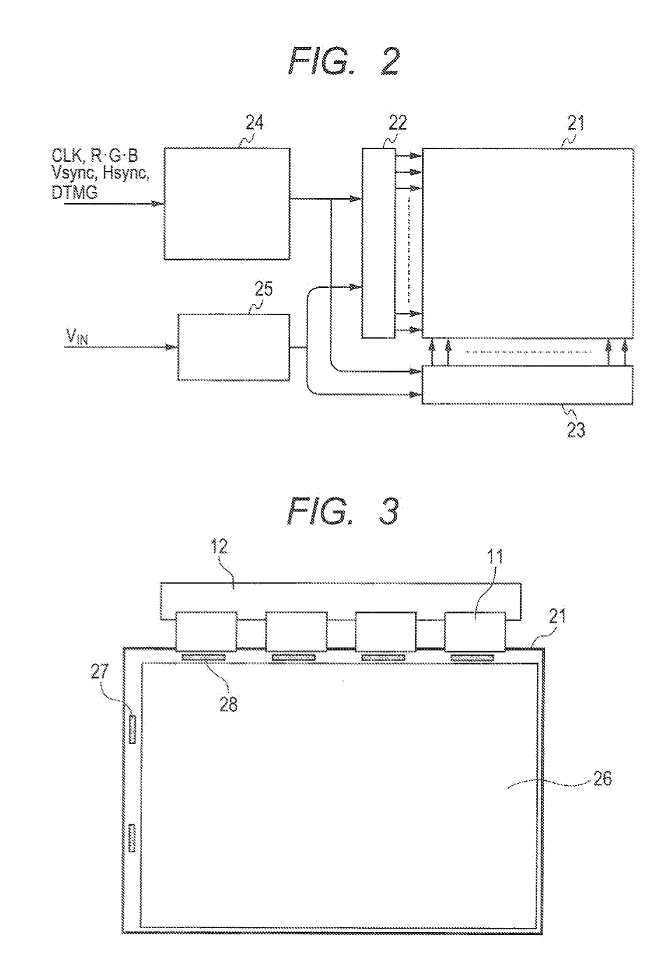

FIG. 2 is a block diagram illustrating a schematic configuration of the driving system of the liquid crystal display device.

The liquid crystal display device includes a liquid crystal display panel 21, a gate driver 22, a drain driver 23, a display control circuit 24, and a power supply circuit 25.

The liquid crystal display panel 21 includes multiple gate signal lines extending in the horizontal direction, multiple data signal lines extending in the vertical direction, and thin-film transistors and pixel electrodes that are disposed at the intersections of the gate signal lines and the data signal lines. The gate driver 22 is connected to the gate signal lines and the drain driver 23 is connected to the data signal lines.

The gate driver 22 and the drain driver 23 are installed along the periphery of the liquid crystal display panel 21. The gate driver 22 includes multiple gate driver ICs disposed along one side of the liquid crystal display panel 21. The drain driver 23 includes multiple drain driver ICs disposed along another side of the liquid crystal display panel 21.

The display control circuit 24 performs a timing adjustment such as alternating of data, suitably for the display of the liquid crystal display panel, on a display signal inputted from a display signal source (host), e.g., a personal computer and a television receiving circuit. The display control circuit 24 then converts the signal to display data in display format and transmits the signal to the gate driver 22 and the drain driver 23 with a synchronizing signal (clock signal). The gate driver 22 and the drain driver 23 supply gate signals to the gate signal lines of the liquid crystal display panel 21 under the control of the display control circuit 24, and supply the display data to the data signal lines to display an image on the liquid crystal display panel 21.

The power supply circuit 25 generates various, voltages required for the liquid crystal display device and supplies the voltages to the circuits.

FIG. 3 illustrates a structural example of the liquid crystal display device.

The liquid crystal display panel. 21 includes a display area 26 that contains pixel electrodes arranged in a matrix on a glass substrate. Moreover, multiple gate driver ICs 27 and multiple drain driver ICs 28 are mounted along peripheral sides of the glass substrate by COG mounting.

A drain substrate (circuit board) 12 includes, for example, an electronic device for driving the drain driver ICs 23 of the display control circuit 24 and so on illustrated in FIG. 2. The drain substrate 12 and the drain driver ICs 28 of the liquid crystal display panel 21 are electrically connected to each other via a flexible printed circuit board (FPC) or chip on films (COFs) 11.

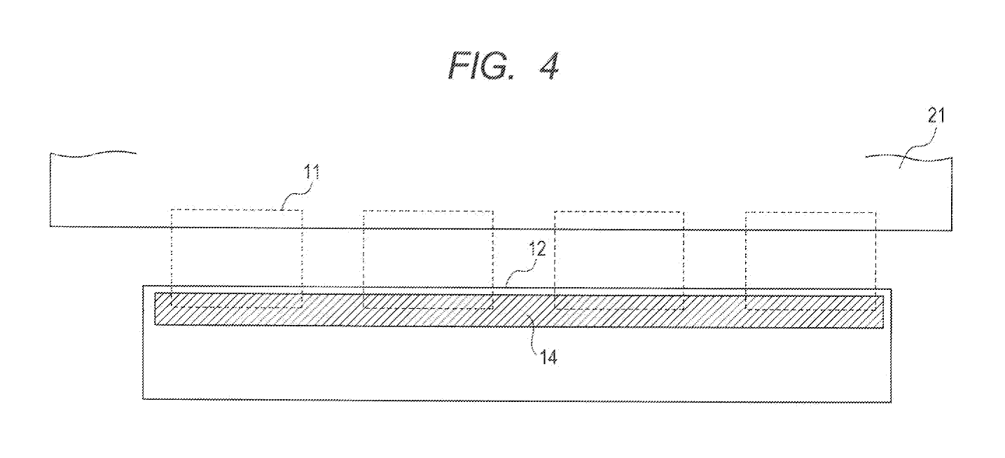

FIG. 4 illustrates a terminal layout area for connecting the FPC or the COFs 11 by crimping on the drain substrate 12. FIG. 4 is vertically flipped from FIG. 3. In FIG. 4, a crimp contact part 14 is provided on one side of the drain substrate 12. The FPC or the COFs 11 are connected to the crimp contact part 14 by crimping.

Specifically, an anisotropic conductive film containing conductive particles dispersed in adhesive resin is disposed between terminals on the drain substrate 12 and the terminals of the FPC or the COFs 11, and then the drain substrate 12 and the FPC or the COFs 11 are electrically connected to each other by thermocompression bonding.

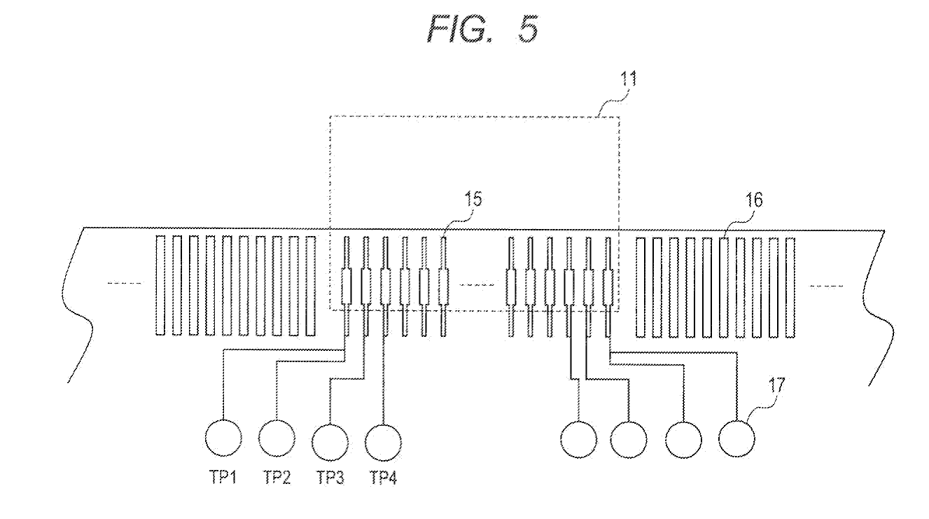

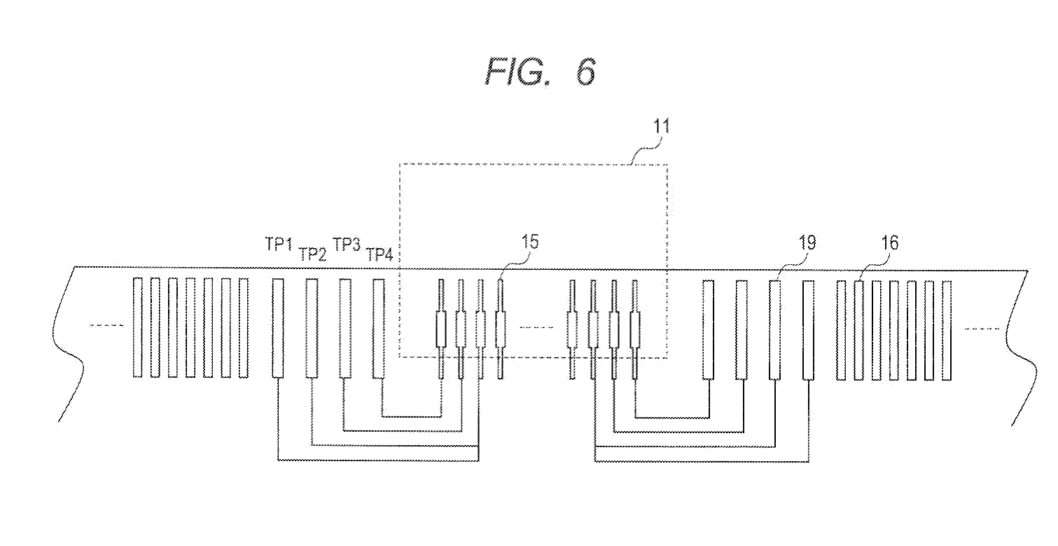

FIG. 5 illustrates the shapes and layout of conventional crimp contacts.

Multiple crimp contacts 15 are provided in the mounting area of an FPC or a COF along one side of a circuit board (e.g., a drain substrate or a gate substrate). The crimp contacts 15 are connected to the FPC or a COF 11 by crimping via an anisotropic conductive film.

Moreover, multiple dummy terminals 16 are provided on both sides of the crimp contacts 15 outside the mounting area of the FPC or the COF and are arranged along the one side of the substrate. The crimp dummy terminals make uniform crimping heat on a printed circuit board (PCB) and serve as a margin for bonding the anisotropic conductive film (ACF). The crimp dummy terminals are typically disposed on both sides of the crimp contacts. The dummy terminals 16 are not connected or electrically active on the circuit.

In FIG. 5, three of the crimp contacts 15 on each side serve as crimp contact measuring terminals connected to test terminals 17. A crimp resistance is measured using terminals TP1, TP2, TP3, and TP4 of the test terminals 17 according to two-terminal measurement or four-terminal measurement.

According to the shapes and layout of the conventional crimp contacts, the test terminals 17 for measuring a crimp resistance have to be disposed in an inner part of the substrate, that is, outside the area of the crimp contacts 15 and the dummy terminals 16 in FIG. 5. Thus, a space for the test terminals is necessary and the mounting area of an, electronic component is limited, resulting in difficulty in arranging the electronic component.

### First Embodiment

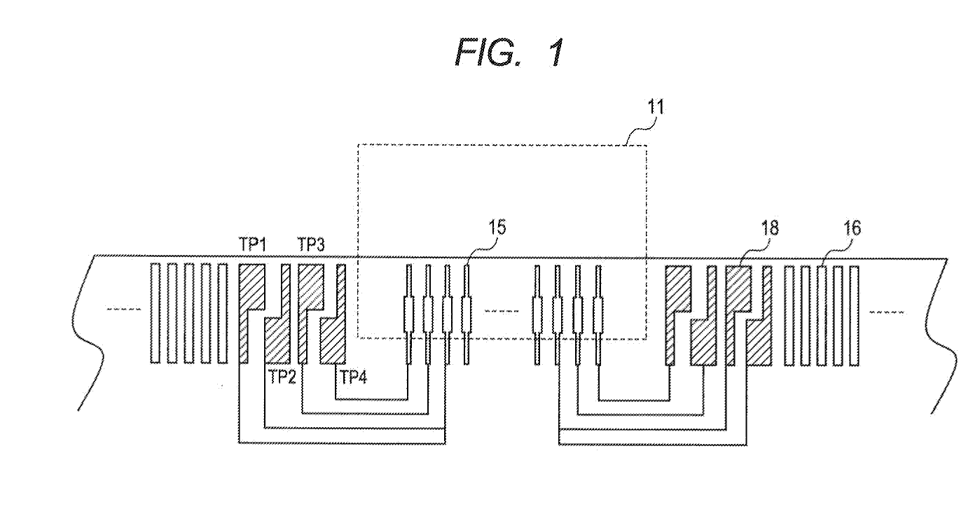

FIG. 1 illustrates the shapes of crimp contacts and a connection diagram according to the first embodiment of the present invention.

As in the conventional configuration, a circuit board (e.g., a drain substrate or a gate substrate) includes multiple crimp contacts 15 (first terminals) in the mounting area of an FPC or a COF (that is, an area where the circuit board and the FPC or the COF overlap each other) along one side of the circuit board. The crimp contacts 15 are connected to the FPC or a COF 11 by crimping via an anisotropic conductive film. In non-crimping areas on both sides of the crimp contacts 15, multiple dummy terminals 16 (second terminals) are provided along one side of the substrate.

Furthermore, test terminals 18 (third terminals) for crimp resistance measurement are disposed on both sides of the crimp contacts 15, that is, at points where the dummy terminals of the conventional configuration are located. Three of the crimp contacts 15 on each side are connected to the test terminals 18 via wiring of a printed circuit board.

As illustrated in FIG. 1, the test terminal 18 preferably has a different shape from the dummy terminal 16 to facilitate probing of measurement.

FIG. 1 illustrates a part of the crimp contacts. As illustrated in FIG. 4, the multiple FPCs or COFs 11 are disposed on a drain substrate 12 and thus typically, the crimp contacts 15 and the dummy terminals 16 are alternately arranged in a line along one side of the printed circuit board.

A crimp resistance is measured using terminals TP1, TP2, TP3, and TP4 of the test terminals 18 by means of a measuring instrument such as a tester according to two-terminal measurement or four-terminal measurement. A crimp resistance is measured mainly to confirm variations in manufacturing steps.

A connection resistance value across the crimp contacts 15 and the FPC or the COF 11 is not larger than 1Ω. Thus, a connection resistance across the crimp contact 15 and the test terminal 18 needs to be equal on the right and left on the printed circuit board.

In the case of the test terminals 17 of the conventional configuration in FIG. 5, the layout of the terminals 17 varies between the right and left sides in the substrate wiring layout, unfortunately leading to variations in the accuracy of resistance measurement between the test terminals on the right and left sides.

In the present embodiment, the locations of the test terminals 18 are fixed, so that a resistance measurement error is small between the right and left sides and the accuracy of measurement is improved.

According to the present embodiment, the test terminals 18 are disposed at the locations of the dummy terminals 16 of the conventional configuration. Thus, an area for component mounting and wiring can be increased and the width of the substrate can be reduced. The test terminals 18 disposed at the dummy terminal portions can act as the dummy terminals of the conventional configuration.

Moreover, according to the present embodiment, a capacitor component for power supply can be disposed next to the crimp contacts 15, further stabilizing a driver operation (preventing oscillation).

The test terminals 18 are disposed on both sides of the crimp contacts 15 and are arranged in a line along one side of the printed circuit board, thereby facilitating measurement. Moreover, a crimp resistance can be automatically measured by a prober.

### Second Embodiment

FIG. 6 illustrates the shapes of crimp contacts and a connection diagram according to a second embodiment of the present invention.

The second embodiment is different from the first embodiment in the shape of a test terminal. In the present embodiment, test terminals 19 are rectangular like dummy terminals 16. The test terminals 19 are distinguished from the dummy terminals 16 by larger intervals than those of the dummy terminals 16. Thus, the test terminals 19 can be identified without being varied in shape from the dummy terminals 16.

### Third Embodiment

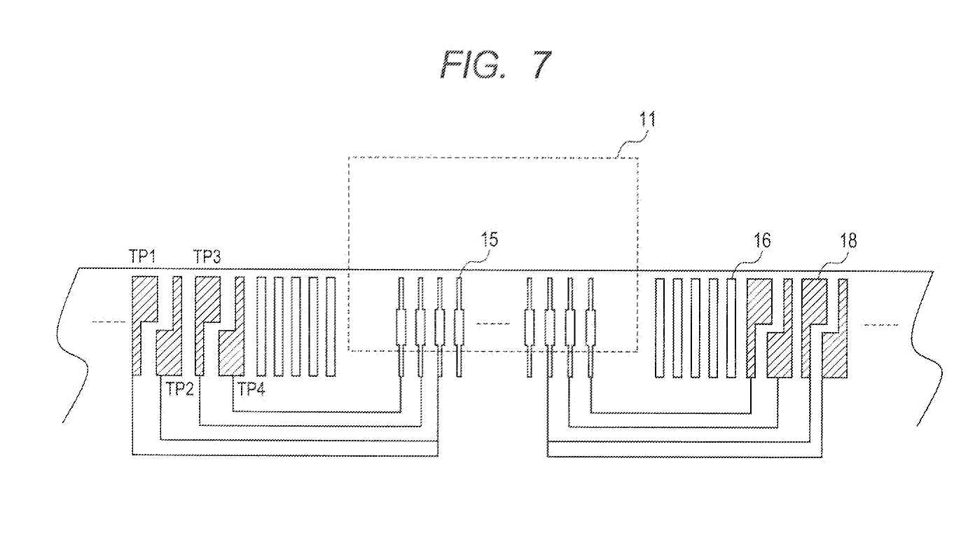

FIG. 7 illustrates the shapes of crimp contacts and a connection diagram according to a third embodiment of the present invention.

The third embodiment is different from the first embodiment in the positions of test terminals. In the first embodiment, the test terminals 18 are disposed near both sides of the crimp contacts 15, whereas in the third embodiment, test terminals 18 are disposed next to dummy terminals 16 on both sides of crimp contacts 15 and are separated from the crimp contacts 15, facilitating probing more than in the first embodiment.

The liquid crystal display devices were illustrated in the foregoing embodiments of the present embodiment. The present invention is not limited to a liquid crystal display device and is also applicable to display devices Such as an organic EL display and a plasma display.

Furthermore, the printed circuit boards (PCB), which are rigid substrates, were illustrated in the embodiments of the present invention. The present invention is not limited to a printed circuit board and is also applicable to various substrates of display devices, e.g., a flexible printed circuit board (FPC) or the substrate of a liquid crystal display panel. These substrates are connected by crimping with an anisotropic conductive film.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a display panel;
a circuit board; and
a flexible printed circuit board connecting the display panel and the circuit board,
the flexible printed circuit board being electrically connected to at least one of substrates of the display panel and the circuit board via an anisotropic conductive film,
wherein the one of the substrates and the circuit board has a mounting area superimposed on the flexible printed circuit board,
the mounting area of the one of the substrates and the circuit board contains a plurality of first terminals, an area other than the mounting area contains second terminals unconnected to the first terminals and third terminals respectively connected to the first terminals, and
the first terminals include terminals connected to the third terminals and terminals unconnected to the third terminals.

2. The display device according to claim 1, wherein the first terminals, the second terminals, and the third terminals are arranged in a line along one side of the one of the substrates and the circuit board.

3. The display device according to claim 1, wherein the third terminal has a different shape from the second terminal.

4. The display device according to claim 1, wherein the second terminals and the third terminals are identical in shape and the third terminals are spaced at intervals different from those of the second terminals.

5. The display device according to claim 1, wherein the second terminals are disposed on both sides of the first terminals and the third terminals are disposed on an opposite side of the second terminals from the first terminals.

6. The display device according to claim 1, wherein the display panel includes a drive circuit installed by COG mounting.

7. The display device according to claim 1, wherein the flexible printed circuit board includes a drive circuit installed by COF mounting.

8. The display device according to claim 1, wherein the display panel is one of a liquid crystal display panel, an organic EL display panel, and a plasma display panel.
